(19) United States
(12) Patent Application Publication
(10) Pub. No.: US 2026/0020331 A1
(43) Pub. Date: Jan. 15, 2026

(54) SEMICONDUCTOR DEVICES COMPRISING PILLAR STRUCTURE

(71) Applicant: Samsung Electronics Co., Ltd., Suwon-si (KR)

(72) Inventors: CHANGDEOK SEO, Suwon-si (KR); MYUNGIL KANG, Suwon-si (KR); KYUNAM PARK, Suwon-si (KR); DOYOUNG CHOI, Suwon-si (KR); WOOHYEON CHOI, Suwon-si (KR)

(21) Appl. No.: 19/002,852

(22) Filed: Dec. 27, 2024

(30) Foreign Application Priority Data
Jul. 15, 2024 (KR) 10-2024-0093248

(51) Int. Cl. H10D 84/83; H10D 30/00; H10D 30/01; H10D 62/10; H10D 84/01

(52) U.S. Cl. CPC H10D 84/832; H10D 30/502; H10D 62/121; H10D 84/013; H10D 30/0191; H10D 84/0151

(57) ABSTRACT

A semiconductor device may include a substrate that comprises a first active pattern and a second active pattern that are spaced apart from each other; a first channel structure on the first active pattern; a first source/drain pattern on the first channel structure; a first pillar structure between the first active pattern and the second active pattern; and a second pillar structure on the first pillar structure, wherein the first pillar structure comprises a first upper surface that is in contact with the second pillar structure and a second upper surface that is higher than the first upper surface, wherein the first upper surface of the first pillar structure is lower than an uppermost surface of the first channel structure, wherein the second upper surface of the first pillar structure is lower than an upper surface of the second pillar structure.

### CROSS-REFERENCE TO RELATED APPLICATIONS

This U.S. non-provisional patent application claims priority under 35 U.S.C. § 119 to Korean Patent Application No. 10-2024-0093248, filed on Jul. 15, 2024, in the Korean Intellectual Property Office, the entire contents of which are hereby incorporated by reference.

### BACKGROUND OF THE INVENTION

The present disclosure relates to semiconductor devices, and in particular, to semiconductor devices including a pillar structure.

A semiconductor device may include an integrated circuit comprising metal-oxide-semiconductor field-effect transistors (MOS-FETs). To meet an increasing demand for a semiconductor device with a small pattern size and a reduced design rule, the MOS-FETs are being scaled down. The scale-down of the MOS-FETs may lead to deterioration in operation characteristics of the semiconductor device. A variety of studies are conducted to overcome technical hurdles associated with the scale-down of the semiconductor device and to provide high performance semiconductor device.

### SUMMARY OF THE INVENTION

An embodiment of the inventive concept may provide a semiconductor device with improved electrical and reliability characteristics.

According to an embodiment of the inventive concept, a semiconductor device may include a substrate that comprises a first active pattern and a second active pattern that are spaced apart from each other in a first direction; a first channel structure on the first active pattern; a first source/drain pattern on the first channel structure; a first pillar structure between the first active pattern and the second active pattern; and a second pillar structure on the first pillar structure, wherein the first pillar structure comprises a first upper surface that is in contact with the second pillar structure and a second upper surface that is farther than the first upper surface from a lower surface of the substrate in a second direction, wherein the first upper surface of the first pillar structure is closer than an uppermost surface of the first channel structure to the lower surface of the substrate in the second direction, wherein the second upper surface of the first pillar structure is closer than an upper surface of the second pillar structure to the lower surface of the substrate in the second direction, wherein the first direction is parallel with the lower surface of the substrate, and wherein the second direction is perpendicular to the lower surface of the substrate.

According to an embodiment of the inventive concept, a semiconductor device may include a substrate that comprises a first active pattern and a second active pattern that are spaced apart from each other in a first direction; a first channel structure that overlaps the first active pattern in a second direction; a first source/drain pattern that is electrically connected to the first channel structure; a first pillar structure between the first active pattern and second active pattern; and a second pillar structure on the first pillar structure, wherein the second pillar structure comprises: a lower surface in contact with the first pillar structure; an upper surface farther than an upper surface of the first source/drain pattern from a lower surface of the substrate in the second direction; and a first side surface that is on the lower surface of the second pillar structure and on the upper surface of the second pillar structure, wherein the first side surface of the second pillar structure is in contact with the first source/drain pattern, wherein the first direction is parallel with the lower surface of the substrate, and wherein the second direction is perpendicular to the lower surface of the substrate.

According to an embodiment of the inventive concept, a semiconductor device may include a substrate that comprises a first active pattern and a second active pattern that are spaced apart from each other in a first direction; a first channel structure that overlaps the first active pattern in a second direction; a second channel structure that overlaps the second active pattern in the second direction; a first gate electrode that overlaps the first active pattern in the first direction and/or the second direction; a second gate electrode that overlaps the second active pattern in the first direction and/or the second direction; a first source/drain pattern that is electrically connected to the first channel structure; a second source/drain pattern that is electrically connected to the second channel structure; a first pillar structure between the first channel structure and the second channel structure in the first direction; an insulating isolation layer between the first active pattern and the first pillar structure; a second pillar structure on the first pillar structure; and a gate spacer on a side surface of the first gate electrode, wherein the gate spacer is between the first pillar structure and the second pillar structure, wherein the first direction is parallel with a lower surface of the substrate, and wherein the second direction is perpendicular to the lower surface of the substrate.

### BRIEF DESCRIPTION OF THE DRAWINGS

FIG. 1A is a plan view illustrating a semiconductor device according to some embodiments of the inventive concept.

FIG. 1B is a sectional view taken along a line A-A′ of FIG. 1A.

FIG. 1C is a sectional view taken along a line B-B′ of FIG. 1A.

FIG. 1D is a sectional view taken along a line C-C′ of FIG. 1A.

FIG. 1E is a sectional view taken along a line D-D′ of FIG. 1A.

FIG. 1F is an enlarged view illustrating a portion ‘E’ of FIG. 1C.

FIGS. 2A, 3A, 7A, and 8A are plan views illustrating a method of fabricating a semiconductor device and FIGS. 2B, 2C, 2D, 3B, 3C, 3D, 3E, 4A, 4B, 4C, 4D, 5A, 5B, 5C, 5D, 6A, 6B, 6C, 6D, 7B, 7C, 7D, 7E, 8B, 8C, and 8D are sectional views illustrating the method of fabricating the semiconductor device, according to some embodiments of the inventive concept.

### DETAILED DESCRIPTION

Example embodiments of the inventive concepts will now be described more fully with reference to the accompanying drawings, in which example embodiments are shown.

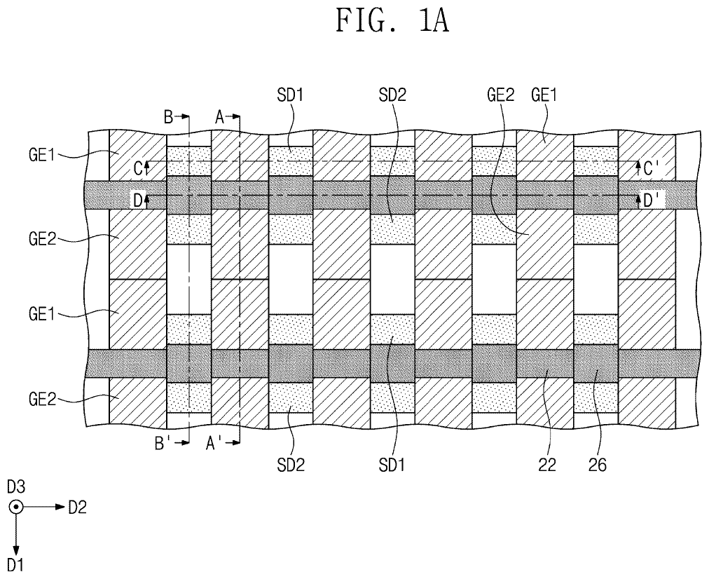

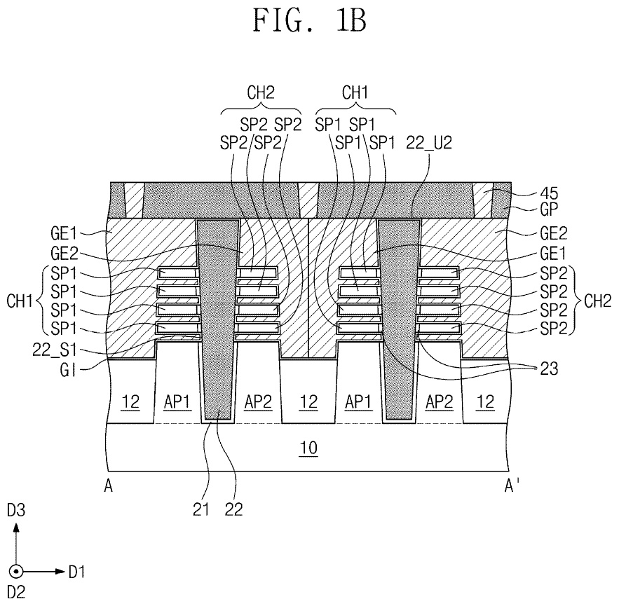

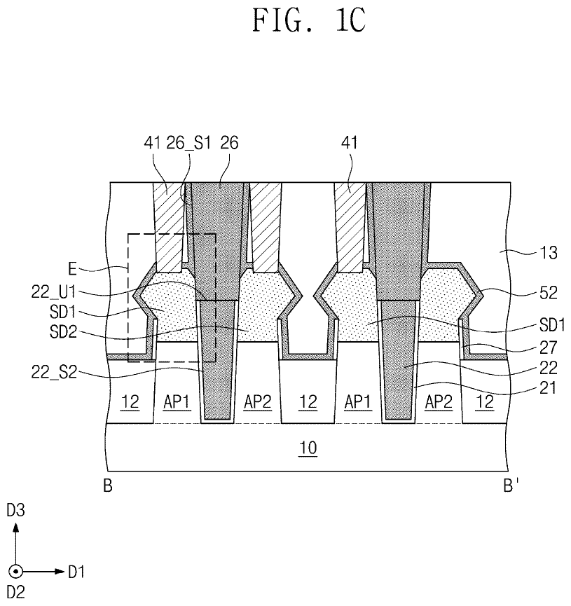

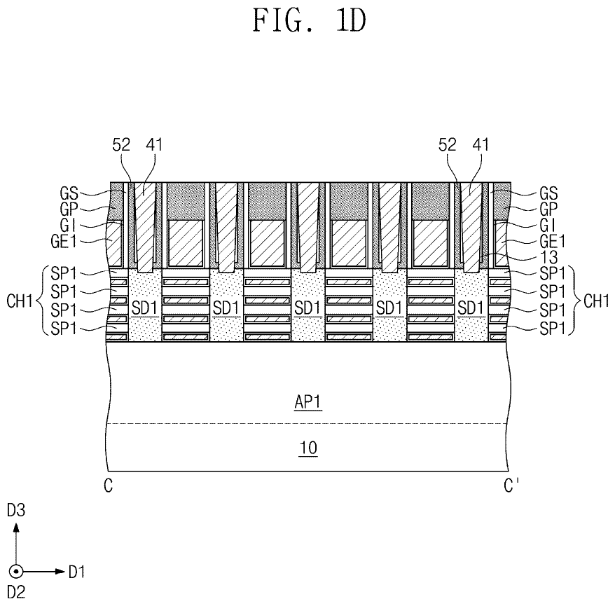

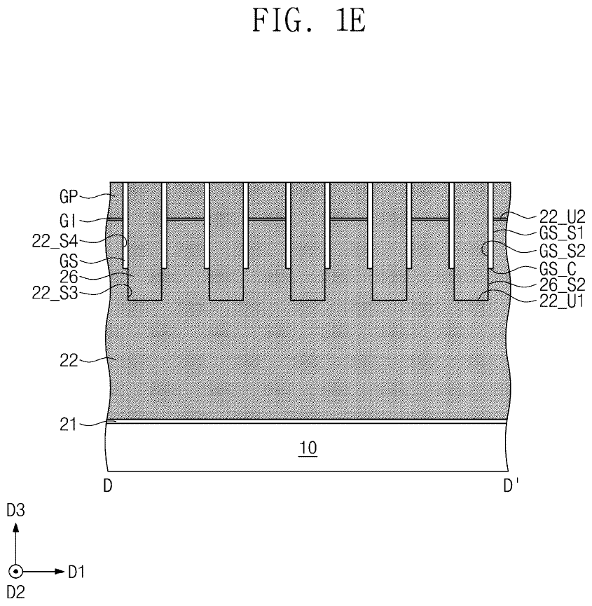

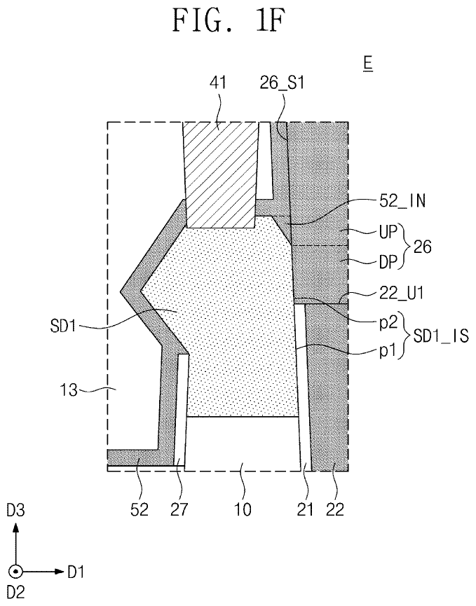

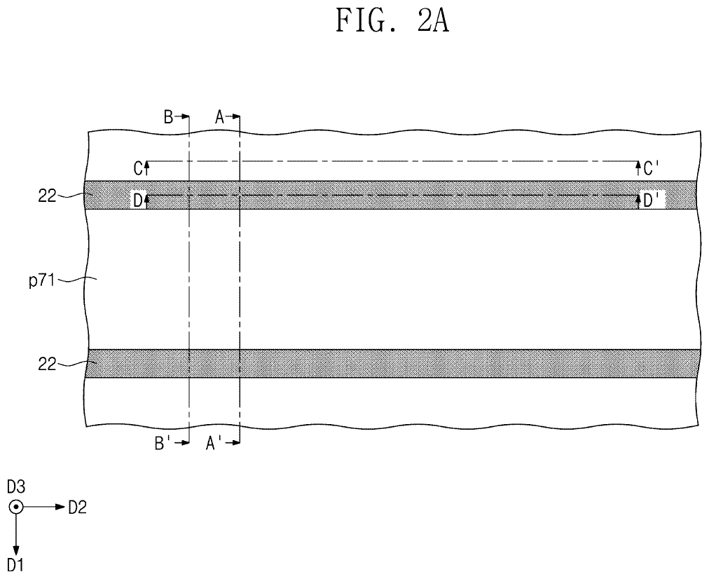

FIG. 1A is a plan view illustrating a semiconductor device according to some embodiments of the inventive concept. FIG. 1B is a sectional view taken along a line A-A′ of FIG. 1A. FIG. 1C is a sectional view taken along a line B-B′ of FIG. 1A. FIG. 1D is a sectional view taken along a line C-C′ of FIG. 1A. FIG. 1E is a sectional view taken along a line D-D′ of FIG. 1A. FIG. 1F is an enlarged view illustrating a portion ‘E’ of FIG. 1C.

Referring to FIGS. 1A to 1F, a semiconductor device may include a substrate 10. Logic transistors constituting a logic circuit may be disposed on the substrate 10. The substrate 10 may be a semiconductor substrate, an insulating substrate, a silicon-on-insulator (SOI) substrate, or a germanium-on-insulator (GOI) substrate. In an embodiment, the semiconductor substrate may be formed of or include Si, Ge, SiGe, GaP, and/or GaAs.

The substrate 10 may be a plate-shaped structure that is extended in a first direction D1 and a second direction D2. The first and second directions D1 and D2 may not be parallel to each other. The first and second directions D1 and D2 may intersect each other. As an example, the first and second directions D1 and D2 may be horizontal directions that are orthogonal to each other. The first and second directions D1 and D2 may be parallel with an upper surface and/or a lower surface of the substrate 10.

The substrate 10 may include first active patterns AP1 and second active patterns AP2. Each of the first and second active patterns AP1 and AP2 may be extended in the second direction D2. The first and second active patterns AP1 and AP2 may be sequentially (e.g., alternately) arranged in the first direction D1. The first and second active patterns AP1 and AP2 may be spaced apart from each other in the first direction D1. The first and second active patterns AP1 and AP2 may be adjacent to each other in the first direction D1. Each of the first and second active patterns AP1 and AP2 may be an upper portion of the substrate 10 protruding in a third direction D3. The third direction D3 may not be parallel to the first and second directions D1 and D2. For example, the third direction D3 may intersect the first direction D1 and the second direction D2. In an embodiment, the third direction D3 may be a vertical direction that is orthogonal to the first and second directions D1 and D2. The third direction D3 may be perpendicular to the upper surface and/or the lower surface of the substrate 10.

Device isolation layers 12 may be provided on the substrate 10. The device isolation layers 12 may be arranged in the first direction D1. The device isolation layers 12 may be spaced apart from each other (in the first direction D1). The device isolation layer 12 may be provided between the (adjacent) first and second active patterns AP1 and AP2 (in the first direction D1). The device isolation layer 12 may include, for example, an insulating material. As an example, the device isolation layer 12 may include an oxide material.

First channel structures CH1 may be provided to overlap with the first active pattern AP1 in the third direction D3, and second channel structures CH2 may be provided to overlap with the second active pattern AP2 in the third direction D3. The first channel structures CH1 may be on the first active pattern AP1, and the second channel structures CH2 may be on the second active pattern AP2.

The channel structures CH1 and CH2, which are overlapped with the active pattern AP1 and AP2 in the third direction D3, may be arranged in the second direction D2. For example, the first channel structures CH1, which are overlapped with the first active pattern AP1 in the third direction D3, may be arranged in the second direction D2. The second channel structures CH2, which are overlapped with the second active pattern AP2 in the third direction D3, may be arranged in the second direction D2. The channel structures CH1 and CH2, which are overlapped with the active pattern AP1 and AP2 in the third direction D3, may be spaced apart from each other in the second direction D2. For example, the first channel structures CH1, which are overlapped with the first active pattern AP1 in the third direction D3, may be spaced apart from each other in the second direction D2. The second channel structures CH2, which are overlapped with the second active pattern AP2 in the third direction D3, may be spaced apart from each other in the second direction D2.

Each of the first channel structures CH1 may include first semiconductor patterns SP1 arranged in the third direction D3. The first semiconductor patterns SP1 may be spaced apart from each other in the third direction D3. Each of the second channel structures CH2 may include second semiconductor patterns SP2 arranged in the third direction D3. The second semiconductor patterns SP2 may be spaced apart from each other in the third direction D3.

The number of the semiconductor patterns SP1 and SP2 in each of the channel structure CH1 and CH2 is not limited to that in the illustrated example. In an embodiment, the number of the first semiconductor patterns SP1 in the first channel structure CH1 may be less than or equal to 3 or may be greater than or equal to 5. In an embodiment, the number of the second semiconductor patterns SP2 in the second channel structure CH2 may be less than or equal to 3 or may be greater than or equal to 5.

In an embodiment, the first and second semiconductor patterns SP1 and SP2 may be formed of or include silicon (Si). For example, the first and second semiconductor patterns SP1 and SP2 may be formed of or include crystalline silicon.

First source/drain patterns SD1 and second source/drain patterns SD2 may be provided. The first source/drain pattern SD1 may be provided on the first active pattern AP1. The second source/drain pattern SD2 may be provided on the second active pattern AP2. The first source/drain pattern SD1 may be overlapped with the first active pattern AP1 in the third direction D3. The second source/drain pattern SD2 may be overlapped with the second active pattern AP2 in the third direction D3. The first source/drain pattern SD1 may be disposed between the first channel structures CH1, which are adjacent to each other in the second direction D2. The second source/drain pattern SD2 may be disposed between the second channel structures CH2, which are adjacent to each other in the second direction D2. The first source/drain pattern SD1 may be (electrically) connected to the first semiconductor patterns SP1 of the first channel structure CH1. The second source/drain pattern SD2 may be (electrically) connected to the second semiconductor patterns SP2 of the second channel structure CH2.

Each of the first and second source/drain patterns SD1 and SD2 may be an epitaxial pattern, which is formed by a selective epitaxial growth process. Each of the first and second source/drain patterns SD1 and SD2 may be formed of or include, for example, silicon (Si) or silicon-germanium (SiGe).

Each of the first and second source/drain patterns SD1 and SD2 may include impurities. In an embodiment, the first and second source/drain patterns SD1 and SD2 may be doped to have the same conductivity type. As an example, the conductivity type of the first and second source/drain patterns SD1 and SD2 may be P-type. As an example, the conductivity type of the first and second source/drain patterns SD1 and SD2 may be N-type.

In an embodiment, the first and second source/drain patterns SD1 and SD2 may be doped to have different conductivity types from each other. For example, the first source/drain pattern SD1 may be doped to have a first conductivity type, and the second source/drain pattern SD2 may be doped to have a second conductivity type different from the first conductivity type. As an example, the first conductivity type may be P-type, and the second conductivity type may be an n type. As an example, the first conductivity type may be N-type, and the second conductivity type may be the P-type.

First gate electrodes GE1 may be provided to overlap with the first active pattern AP1 in the third direction D3. The first gate electrode GE1 may be overlapped with the first channel structure CH1 in the third direction D3. The first gate electrode GE1 may be on the first active pattern AP1 and the first channel structure CH1. Second gate electrodes GE2 may be provided to overlap with the second active pattern AP2 in the third direction D3. The second gate electrode GE2 may be overlapped with the second channel structure CH2 in the third direction D3. The second gate electrode GE2 may be on the second active pattern AP2 and the second channel structure CH2.

The first gate electrode GE1 may be disposed between the first source/drain patterns SD1, which are adjacent to each other in the second direction D2. The second gate electrode GE2 may be disposed between the second source/drain patterns SD2, which are adjacent to each other in the second direction D2. In an embodiment, a gate separation structure may be provided on the device isolation layer 12 to separate the first and second gate electrodes GE1 and GE2 from each other.

The first and second gate electrodes GE1 and GE2 and the first and second semiconductor patterns SP1 and SP2 may constitute a three-dimensional field effect transistor (e.g., multi-bridge channel field effect transistor (MBCFET) or gate all around filed effect transistor (GAAFET)).

Insulating isolation layers 21 may be provided. The insulating isolation layers 21 may be extended in the second direction D2. The insulating isolation layers 21 may be spaced apart from each other in the first direction D1. The insulating isolation layer 21 may be disposed between the first and second active patterns AP1 and AP2. The insulating isolation layers 21 and the device isolation layers 12 may be alternately disposed in the first direction D1. The insulating isolation layer 21 may be in contact with the first and second active patterns AP1 and AP2. The insulating isolation layer 21 may include, for example, an insulating material.

First pillar structures 22 may be provided. The first pillar structure 22 may be provided on the insulating isolation layer 21. The first pillar structures 22 may be extended in the second direction D2. The first pillar structures 22 may be spaced apart from each other in the first direction D1. The first pillar structure 22 may be disposed between the first and second active patterns AP1 and AP2, between the first and second channel structures CH1 and CH2, and between the first and second gate electrodes GE1 and GE2 (in the first direction D1). The first pillar structures 22 may be between the first source/drain pattern SD1 and the second source/drain pattern SD2 (in the first direction D1). The first pillar structure 22 may be spaced apart from the first active pattern AP1, the second active pattern AP2, the first source/drain pattern SD1, and the second source/drain pattern SD2 with the insulating isolation layer 21 interposed therebetween. The first pillar structure 22 may be in contact with the insulating isolation layer 21. In some embodiments, the insulating isolation layer 21 may be omitted. The first pillar structure 22 may be in contact with the first source/drain pattern SD1 and the second source/drain pattern SD2. The first pillar structure 22 may include, for example, an insulating material.

Intervening insulating patterns 23 may be provided. The intervening insulating patterns 23 may be spaced apart from each other in the first direction D1, with the first pillar structure 22 interposed therebetween. The intervening insulating patterns 23 may be disposed between the first semiconductor pattern SP1 and the first pillar structure 22 and/or between the second semiconductor pattern SP2 and the first pillar structure 22. The intervening insulating patterns 23 may be in contact with the first pillar structure 22. The intervening insulating pattern 23 may include, for example, an insulating material.

Second pillar structures 26 may be provided. The second pillar structure 26 may be provided on the first pillar structure 22. The second pillar structures 26 may be spaced apart from each other in the first direction D1. The second pillar structure 26 may be disposed between the (adjacent) first and second source/drain patterns SD1 and SD2. The second pillar structure 26 may be in contact with the first pillar structure 22, the insulating isolation layer 21, the first source/drain pattern SD1, and the second source/drain pattern SD2.

Capping insulating layers 27 may be provided. The capping insulating layer 27 may be provided on an upper surface (e.g., a top surface) of the device isolation layer 12. The capping insulating layer 27 may be disposed between the first source/drain pattern SD1 and a cover insulating layer 52 to be described below and/or between the second source/drain pattern SD2 and the cover insulating layer 52. In some embodiments, the capping insulating layer 27 may be between the first active pattern AP1 and the cover insulating layer 52 and/or between the second active pattern AP2 and the cover insulating layer 52. The capping insulating layer 27 may include, for example, an insulating material.

Gate insulating layers GI may be provided. The gate insulating layer GI may separate the first gate electrode GE1 from the first semiconductor patterns SP1 of the first channel structure CH1. The gate insulating layer GI may separate the second gate electrode GE2 from the second semiconductor patterns SP2 of the second channel structure CH2. The gate insulating layer GI may be in contact with the first gate electrode GEL and the first channel structure CH1 (e.g., the first semiconductor patterns SP1). The gate insulating layer GI may be in contact with the second gate electrode GE2 and the second channel structure CH2 (e.g., the second semiconductor patterns SP2). The gate insulating layer GI may be in contact with the first active pattern AP1, the second active pattern AP2, the device isolation layer 12, the insulating isolation layer 21, the first pillar structure 22, and the intervening insulating pattern 23. The gate insulating layer GI may include, for example, an insulating material. As an example, the gate insulating layer GI may include an oxide material.

Gate spacers GS may be provided. The gate spacers GS may be disposed on opposite (e.g., opposite in the second direction D2) side surfaces of the first gate electrode GEL and/or opposite side surfaces of the second gate electrode GE2. The gate spacer GS may be disposed between the first and second pillar structures 22 and 26. The gate spacer GS may be in contact with the first and second pillar structures 22 and 26. The gate spacers GS may include, for example, an insulating material.

Gate capping patterns GP may be provided. The gate capping pattern GP may be provided on the first and second gate electrodes GE1 and GE2. The gate capping pattern GP may include, for example, an insulating material. As an example, the gate capping pattern GP may include a nitride material.

Cover insulating layers 52 may be provided. The cover insulating layer 52 may be provided to extend around (e.g., at least partially surround or enclose) the first source/drain pattern SD1, the second source/drain pattern SD2, the substrate 10, the device isolation layer 12, the first pillar structure 22, and/or the second pillar structure 26. The cover insulating layer 52 may be in contact with the first source/drain pattern SD1, the second source/drain pattern SD2, the substrate 10, the device isolation layer 12, the first pillar structure 22, and/or the second pillar structure 26. The cover insulating layer 52 may include, for example, an insulating material. As an example, the cover insulating layer 52 may include a nitride material.

An insulating layer 13 may be provided on the cover insulating layer 52. The insulating layer 13 may include, for example, an insulating material. As an example, the insulating layer 13 may include an oxide material.

Active contacts 41 may be provided. Each of the active contacts 41 may be provided to extend in (e.g., penetrate) the insulating layer 13 and the cover insulating layer 52 and may be (electrically) connected to the first or second source/drain pattern SD1 or SD2. The active contact 41 may include a conductive material. As an example, the active contact 41 may include a metallic material.

The second pillar structure 26 may be disposed between adjacent ones of the active contacts 41 (in the first direction D1). The adjacent ones of the active contacts 41 may be separated from each other by the second pillar structure 26.

Gate contacts 45 may be provided. Each of the gate contacts 45 may be provided to extend in (e.g., penetrate) the gate capping pattern GP and may be (electrically) connected to the first or second gate electrode GEL or GE2. The gate contact 45 may include a conductive material. As an example, the gate contact 45 may include a metallic material.

The first pillar structure 22 may include a first upper surface 22_U1 (e.g., a first top surface 22_U1), a second upper surface 22_U2 (e.g., a second top surface 22_U2), a first side surface 22_S1, a second side surface 22_S2, a third side surface 22_S3, and a fourth side surface 22_S4. The first upper surface 22_U1 of the first pillar structure 22 may be in contact with (a lower surface and/or a lower portion of) the second pillar structure 26. The second upper surface 22_U2 of the first pillar structure 22 may be in contact with the gate insulating layer GI. The first side surface 22_S1 of the first pillar structure 22 may be in contact with the insulating isolation layer 21, the gate insulating layer GI, and the intervening insulating pattern 23. The first side surface 22_S1 of the first pillar structure 22 may be disposed on the first and second channel structures CH1 and CH2. The second side surface 22_S2 of the first pillar structure 22 may be in contact with the insulating isolation layer 21. The second side surface 22_S2 of the first pillar structure 22 may be disposed between the first and second source/drain patterns SD1 and SD2 (that are adjacent each other in the first direction D1). The third side surface 22_S3 of the first pillar structure 22 may be in contact with the second pillar structure 26. For example, the third side surface 22_S3 of the first pillar structure 22 may be in contact with a lower portion and/or a lower surface (e.g., the bottom surface) of the second pillar structure 26. The fourth side surface 22_S4 of the first pillar structure 22 may be in contact with the gate spacer GS.

The second pillar structure 26 may include a lower surface (e.g., a bottom surface), an upper surface (e.g., a top surface), a first side surface 26_S1, and a second side surface 26_S2. The lower surface of the second pillar structure 26 may be in contact with the first upper surface 22_U1 of the first pillar structure 22 and the insulating isolation layer 21. The upper surface of the second pillar structure 26 may be opposite to the lower surface of the second pillar structure 26 (in the third direction D3). The first side surface 26_S1 of the second pillar structure 26 may connect the lower and upper surfaces of the second pillar structure 26 to each other. The first side surface 26_S1 of the second pillar structure 26 may be in contact with the cover insulating layer 52, the first source/drain pattern SD1, and the second source/drain pattern SD2. The second side surface 26_S2 of the second pillar structure 26 may connect the lower and upper surfaces of the second pillar structure 26 to each other. The second side surface 26_S2 of the second pillar structure 26 may be in contact with the third side surface 22_S3 of the first pillar structure 22 and the gate spacer GS.

The gate spacer GS may include a first side surface GS_S1, a second side surface GS_S2, and a connection surface GS_C (e.g., a lower surface of the gate spacer GS). The first side surface GS_S1 of the gate spacer GS may be in contact with the fourth side surface 22_S4 of the first pillar structure 22. The second side surface GS_S2 of the gate spacer GS may be opposite to the first side surface GS_S1 of the gate spacer GS (in the second direction D2). The second side surface GS_S2 of the gate spacer GS may be in contact with the second side surface 26_S2 of the second pillar structure 26. The connection surface GS_C of the gate spacer GS may connect the first and second side surfaces GS_S1 and GS_S2 of the gate spacer GS to each other. The connection surface GS_C of the gate spacer GS may be in contact with the first pillar structure 22.

The first source/drain pattern SD1 may include an inner side surface SD1_IS. The inner side surface SD1_IS of the first source/drain pattern SD1 may face the second source/drain pattern SD2. The inner side surface SD1_IS of the first source/drain pattern SD1 may include a first portion p1 in contact with the insulating isolation layer 21 and a second portion p2 in contact with the second pillar structure 26. For example, a portion of the inner side surface SD1_IS overlapped with the insulating isolation layer 21 (in the first direction D1) may be defined as the first portion p1, and a portion of the inner side surface SD1_IS overlapped with the second pillar structure 26 (in the first direction D1) may be defined as the second portion p2. In some embodiments, the second portion p2 may overlap a lower pattern DP of the second pillar structure 26 (in the first direction D1) and may not overlap an upper pattern UP of the second pillar structure 26 (in the first direction D1) on the lower pattern DP.

The second pillar structure 26 may include a lower pattern DP and an upper pattern UP on the lower pattern DP. The lower pattern DP of the second pillar structure 26 may be in contact with the first and second source/drain patterns SD1 and SD2. The lower pattern DP of the second pillar structure 26 may be spaced apart from the cover insulating layer 52. In some embodiments, in a cross-sectional view, the lower pattern DP of the second pillar structure 26 and the cover insulating layer 52 may meet at a point but may not share a line. Herein, the term “point” may refer to a location and may not have any length, height, shape, or size. The upper pattern UP of the second pillar structure 26 may be in contact with the cover insulating layer 52. For example, in a cross-sectional view, the upper pattern UP of the second pillar structure 26 may share a line with the cover insulating layer 52. The upper pattern UP of the second pillar structure 26 may be spaced apart from the first and second source/drain patterns SD1 and SD2 (by the cover insulating layer 52 and/or the lower pattern DP of the second pillar structure 26). In some embodiments, in a cross-sectional view, the upper pattern UP of the second pillar structure 26 and the first and second source/drain patterns SD1 and SD2 may meet at a point but may not share a line.

The cover insulating layer 52 may include an intervening portion 52_IN. The intervening portion 52_IN of the cover insulating layer 52 may be disposed between the first source/drain pattern SD1 (and/or the second source/drain pattern SD2) and the second pillar structure 26 (e.g., the upper pattern UP of the second pillar structure 26). The intervening portion 52_IN of the cover insulating layer 52 may be in contact with the first side surface 26_S1 of the second pillar structure 26. The intervening portion 52_IN of the cover insulating layer 52 may be in contact with the upper pattern UP of the second pillar structure 26.

A level of the first upper surface 22_U1 of the first pillar structure 22 may be lower than the uppermost level (e.g., the level of the uppermost surface) of the first channel structure CH1 and the uppermost level (e.g., the level of the uppermost surface) of the second channel structure CH2. Herein, the term “level” may refer to a relative location with respect to a reference element in the third direction D3. A level, a vertical level, or the like may be a distance from the lower surface of the substrate 10 in the third direction D3. For example, a higher level may mean a farther distance from the lower surface of the substrate 10 in the third direction D3, and a lower level may mean a closer distance to the lower surface of the substrate 10 in the third direction D3. The level of the first upper surface 22_U1 of the first pillar structure 22 may be lower than a level of the lower surface (e.g., the bottom surface) of the uppermost one of the first semiconductor patterns SP1. The level of the first upper surface 22_U1 of the first pillar structure 22 may be lower than a level of the lower surface (e.g., the bottom surface) of the uppermost one of the second semiconductor patterns SP2. The level of the first upper surface 22_U1 of the first pillar structure 22 may be lower than a level of the connection surface GS_C of the gate spacer GS. In an embodiment, the level of the first upper surface 22_U1 of the first pillar structure 22 may be lower than a level of the upper surface (e.g., top surface) of the uppermost first semiconductor pattern SP1 and/or the upper surface (e.g., top surface) of the uppermost second semiconductor pattern SP2 and may be higher than a level of the lower surface (e.g., the bottom surface) of the uppermost first semiconductor pattern SP1 and/or the lower surface (e.g., the bottom surface) of the uppermost second semiconductor pattern SP2.

A level of the second upper surface 22_U2 of the first pillar structure 22 may be lower than a level of the upper surface (e.g., the top surface) of the second pillar structure 26. The level of the second upper surface 22_U2 of the first pillar structure 22 may be higher than the level of the connection surface GS_C of the gate spacer GS.

The level of the upper surface (e.g., the top surface) of the second pillar structure 26 may be higher than the uppermost level (e.g., the level of the uppermost surface) of the first source/drain pattern SD1 and the uppermost level (e.g., the level of the uppermost surface) of the second source/drain pattern SD2. A level of the lower surface (e.g., the bottom surface) of the second pillar structure 26 may be lower than the uppermost level (e.g., the level of the uppermost surface) of the first channel structure CH1 and the uppermost level (e.g., the level of the uppermost surface) of the second channel structure CH2. The level of the lower surface (e.g., the bottom surface) of the second pillar structure 26 may be lower than the level of the connection surface GS_C of the gate spacer GS.

The uppermost level (e.g., the level of the uppermost surface) of the insulating isolation layer 21 may be lower than the uppermost level (e.g., the level of the uppermost surface) of the first channel structure CH1 and the uppermost level (e.g., the level of the uppermost surface) of the second channel structure CH2.

A thickness of the lower pattern DP of the second pillar structure 26 (in the third direction D3) may be greater (e.g., larger) than a thickness of the first semiconductor pattern SP1 of the first channel structure CH1 (in the third direction D3) and a thickness of the second semiconductor pattern SP2 of the second channel structure CH2 (in the third direction D3).

A distance between the lower surface (e.g., the bottom surface) and the second upper surface 22_U2 (e.g., the top surface) of the first pillar structure 22 may be less (e.g., smaller) than a distance between the lower surface (e.g., the bottom surface) and the upper surface (e.g., top surface) of the second pillar structure 26.

A width of the first pillar structure 22 (in the first direction D1 and/or the second direction D2) and a width of the second pillar structure 26 (in the first direction D1 and/or the second direction D2) may decrease as a vertical level is lowered. A width of the first upper surface 22_U1 of the first pillar structure 22 may be less (e.g., smaller) than a width of the upper surface (e.g., the top surface) of the second pillar structure 26.

In the semiconductor device according to an embodiment of the inventive concept, the level of the first upper surface 22_U1 of the first pillar structure 22 may be lower than the uppermost level of the first channel structure CH1 and/or the uppermost level of the second channel structure CH2. Thus, a residue may not be left on the second side surface 22_S2 of the first pillar structure 22 in a process of forming the first source/drain pattern SD1 and/or the second source/drain pattern SD2, and this may make it possible to improve the electrical and reliability characteristics of the semiconductor device.

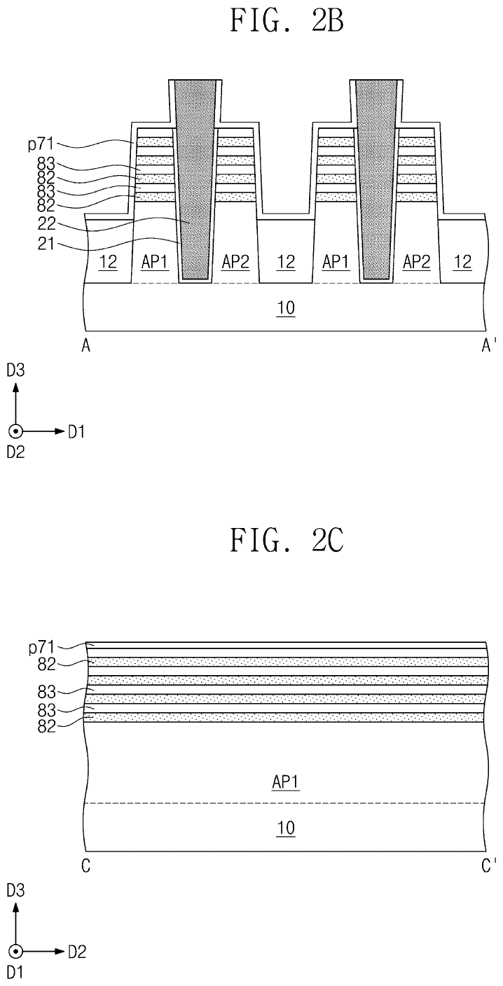

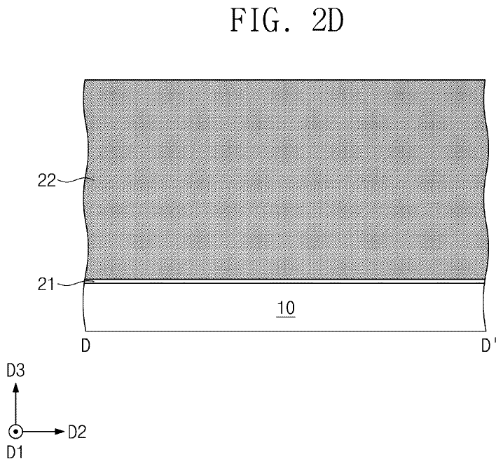

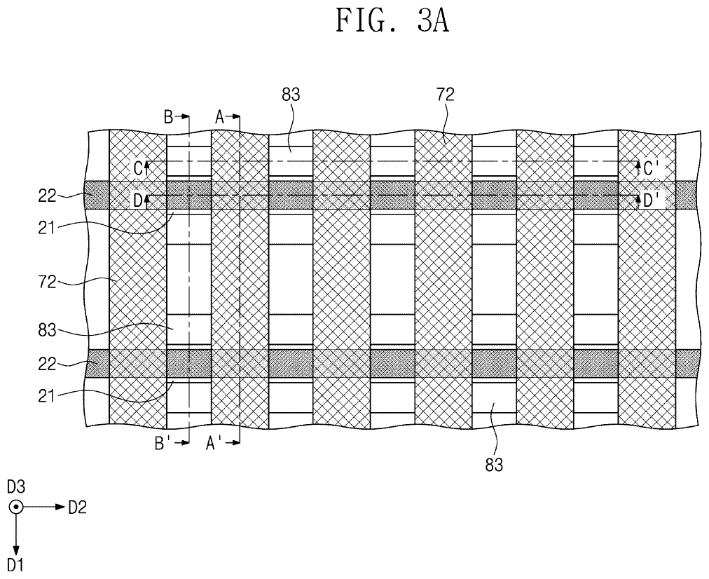

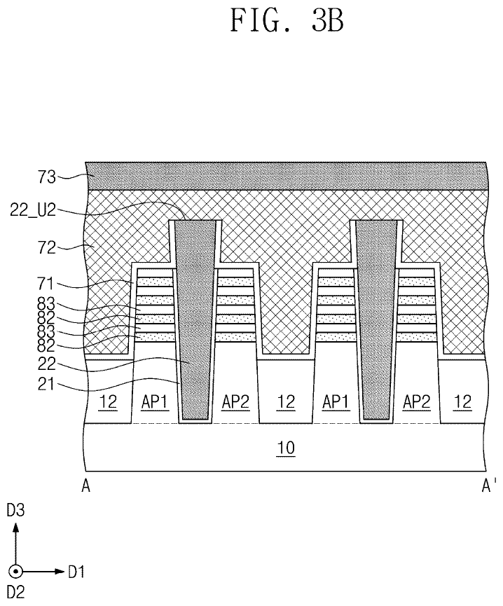

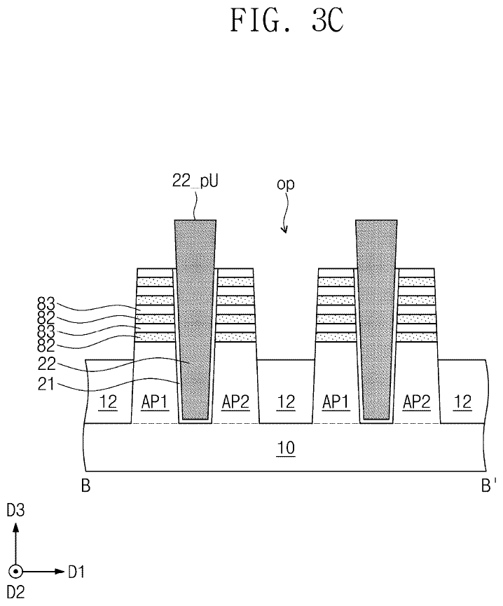

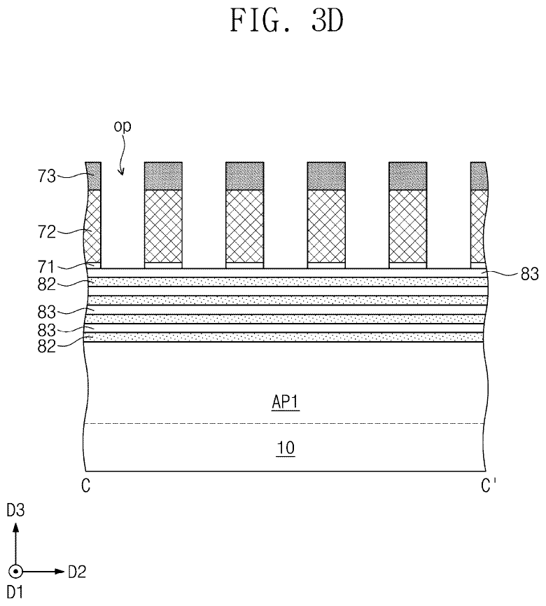

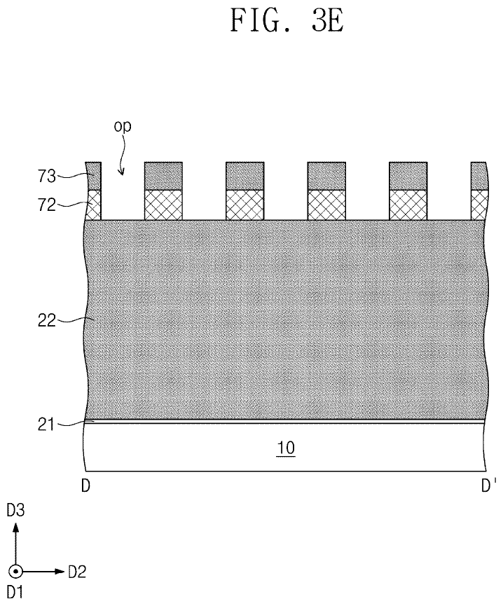

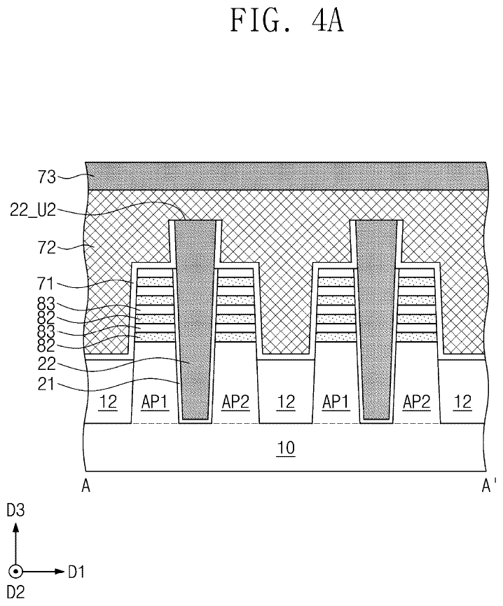

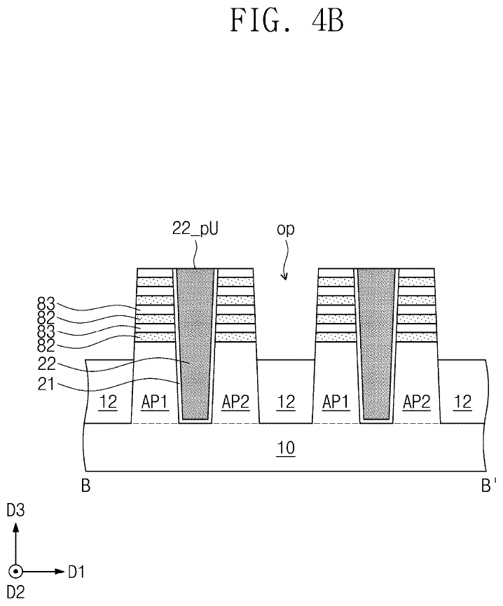

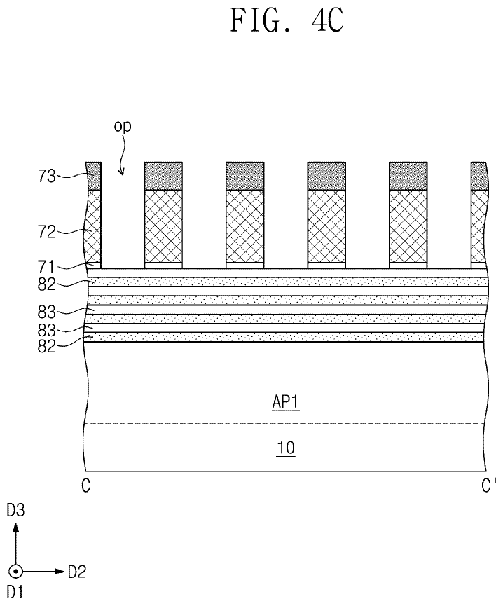

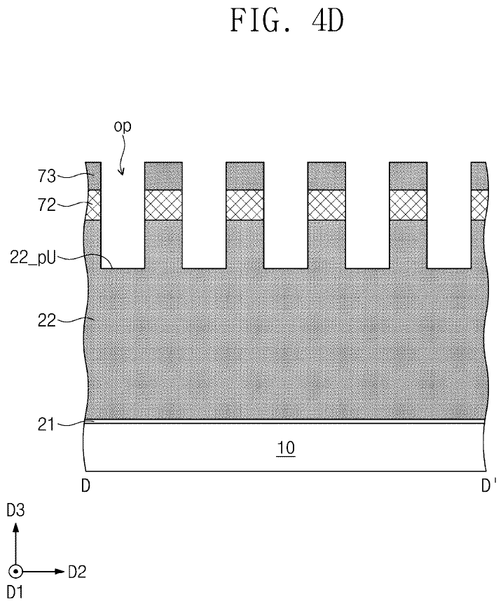

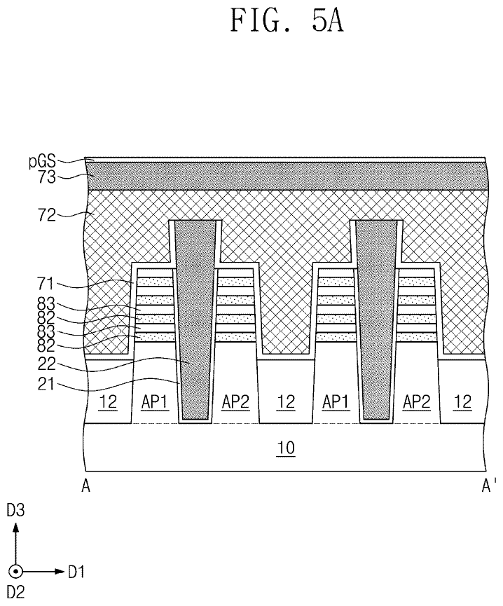

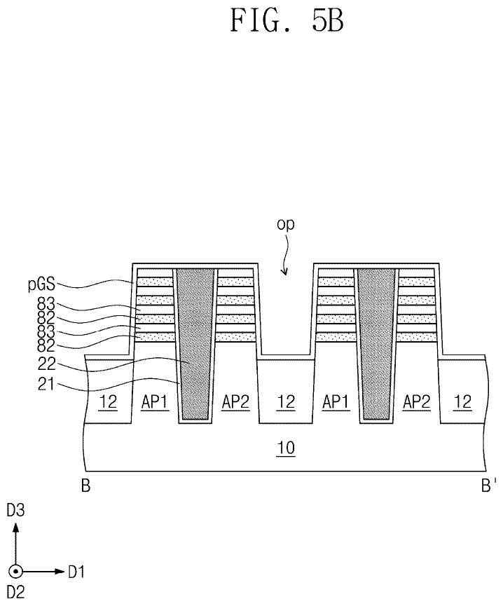

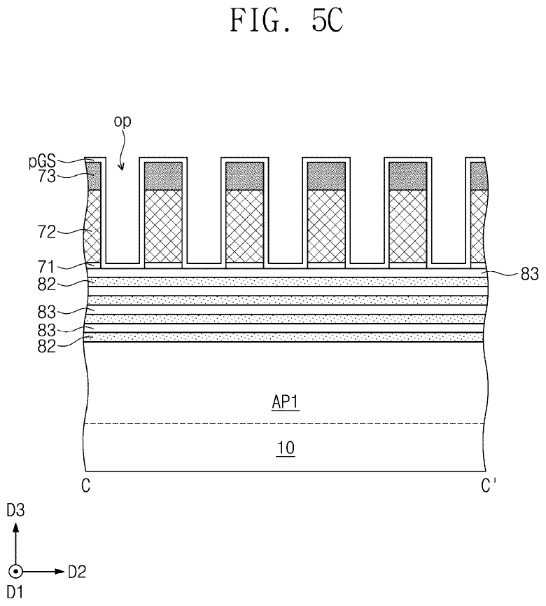

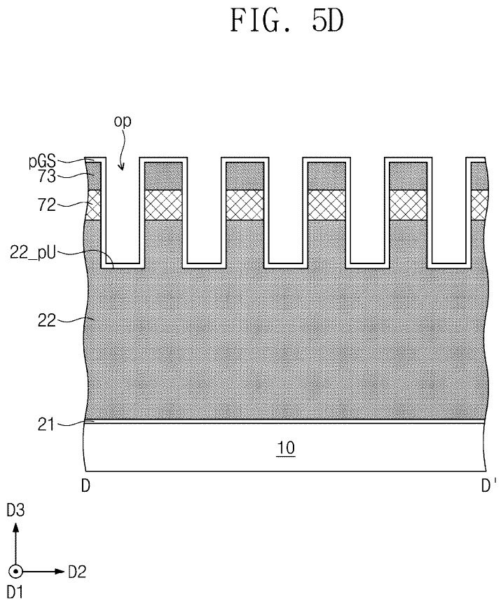

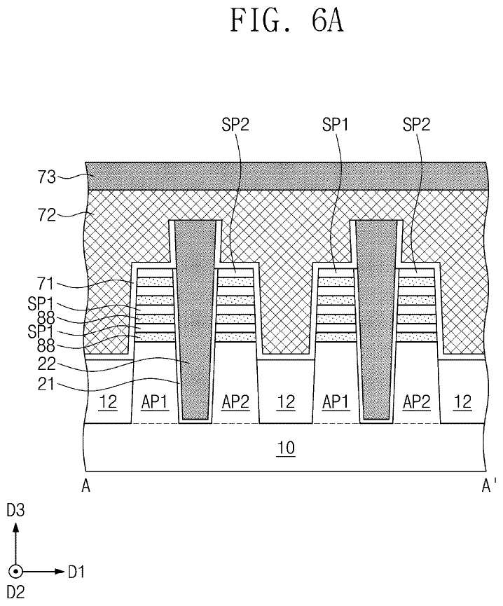

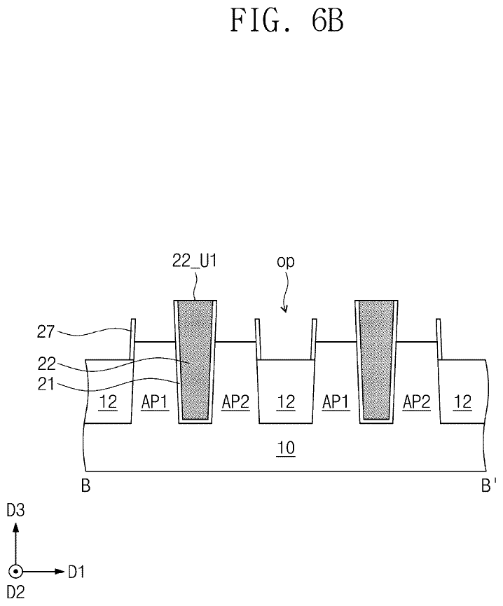

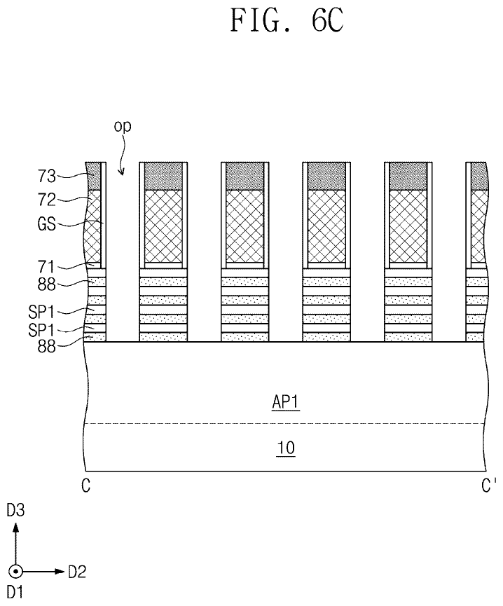

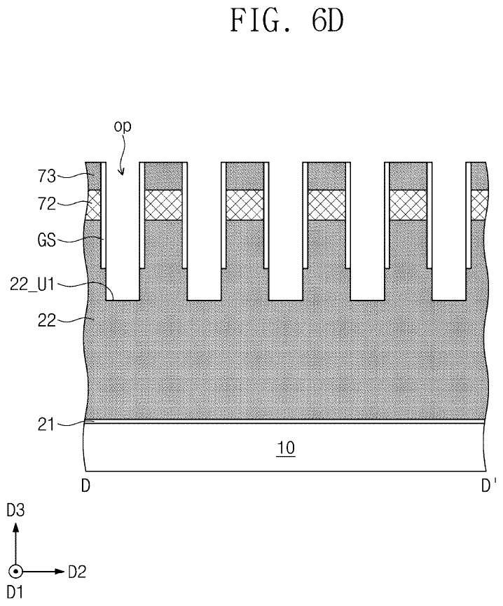

FIGS. 2A, 3A, 7A, and 8A are plan views illustrating a method of fabricating a semiconductor device and FIGS. 2B, 2C, 2D, 3B, 3C, 3D, 3E, 4A, 4B, 4C, 4D, 5A, 5B, 5C, 5D, 6A, 6B, 6C, 6D, 7B, 7C, 7D, 7E, 8B, 8C, and 8D are sectional views illustrating the method of fabricating the semiconductor device, according to some embodiments of the inventive concept. FIGS. 2A, 3A, 7A, and 8A may correspond to FIG. 1A. FIGS. 2B, 3B, 4A, 5A, 6A, 7B, and 8B may correspond to FIG. 1B. FIGS. 3C, 4B, 5B, 6B, 7C, and 8C may correspond to FIG. 1C. FIGS. 2C, 3D, 4C, 5C, 6C, 7D, and 8D may correspond to FIG. 1D. FIGS. 2D, 3E, 4D, 5D, 6D, and 7E may correspond to FIG. 1E.

Referring to FIGS. 2A, 2B, 2C, and 2D, active patterns AP1 and AP2, first semiconductor layers 82, and second semiconductor layers 83 may be formed by a process including steps of forming preliminary semiconductor layers on the substrate 10, forming a mask pattern on the preliminary semiconductor layers, and patterning the preliminary semiconductor layers and the substrate 10 using the mask pattern. The substrate 10 may be patterned to form the active patterns AP1 and AP2. The preliminary semiconductor layers may be patterned to form the first and second semiconductor layers 82 and 83.

Each of the first and second semiconductor layers 82 and 83 may include a semiconductor material. The first and second semiconductor layers 82 and 83 may include different materials. As an example, the first semiconductor layer 82 may be formed of or include silicon-germanium (SiGe), and the second semiconductor layer 83 may be formed of or include silicon (Si).

The device isolation layers 12 and the insulating isolation layers 21 may be formed between the first and second active patterns AP1 and AP2. The first pillar structures 22 may be formed on the insulating isolation layers 21, respectively.

A preliminary sacrificial capping layer p71 may be formed on the active patterns AP1 and AP2, the device isolation layers 12, the insulating isolation layers 21, the first semiconductor layers 82, the second semiconductor layers 83, and the first pillar structures 22. The preliminary sacrificial capping layer p71 may conformally cover the device isolation layers 12, the insulating isolation layers 21, the first semiconductor layers 82, the second semiconductor layers 83, and the first pillar structures 22. The preliminary sacrificial capping layer p71 may include, for example, an insulating material.

An upper portion of the preliminary sacrificial capping layer p71 may be removed. As a result of the removal of the upper portion of the preliminary sacrificial capping layer p71, an upper surface (e.g., a top surface) of the first pillar structure 22 may be exposed (to the outside). For example, the preliminary sacrificial capping layer p71 may expose the upper surface of the first pillar structure 22. As used herein, “an element A exposing an element B” means that at least one portion of the element B is free of contact with the element A. Another portion of the element B may be in contact with the element A. The element B may be in contact with other elements than the element A.

Referring to FIGS. 3A, 3B, 3C, 3D, and 3E, first gate sacrificial layers 71, second gate sacrificial layers 72, and gate mask patterns 73 may be formed. The formation of the first gate sacrificial layers 71, the second gate sacrificial layers 72, and the gate mask patterns 73 may include forming a preliminary gate sacrificial layer on the device isolation layers 12, the first and second semiconductor layers 82 and 83, the preliminary sacrificial capping layer p71, and the first pillar structure 22, forming a preliminary gate mask layer on the preliminary gate sacrificial layer, patterning the preliminary gate mask layer to form the gate mask patterns 73, and patterning the preliminary sacrificial capping layer p71 and the preliminary gate sacrificial layer using the gate mask patterns 73 to form the first gate sacrificial layers 71 and the second gate sacrificial layers 72, respectively. The first gate sacrificial layers 71 may be formed by patterning the preliminary sacrificial capping layer p71. In other words, the first gate sacrificial layers 71 may be a portion of the preliminary sacrificial capping layer p71, which is left after the pattering step.

The preliminary gate mask layer, the preliminary sacrificial capping layer p71, and the preliminary gate sacrificial layer may be patterned to form an opening op. The preliminary gate mask layer, the preliminary sacrificial capping layer p71, and the preliminary gate sacrificial layer may be patterned to expose the upper surface (e.g., the top surface) of the second semiconductor layer 83 and (at least a portion of) the upper surface (e.g., the top surface) of the first pillar structure 22. In other words, the upper surface (e.g., the top surface) of the uppermost second semiconductor layer 83 and (at least a portion of) the upper surface (e.g., the top surface) of the first pillar structure 22 may be exposed through the opening op. The opening op may be defined by upper surface (e.g., top surface) of the uppermost second semiconductor layer 83, the first gate sacrificial layers 71, the second gate sacrificial layers 72, and the gate mask patterns 73.

The first gate sacrificial layers 71, the second gate sacrificial layers 72, and the gate mask patterns 73 may be extended in the first direction D1. The first gate sacrificial layers 71 may be arranged in the second direction D2. The second gate sacrificial layers 72 may be arranged in the second direction D2. The gate mask patterns 73 may be arranged in the second direction D2.

An unexposed portion of the upper surface (e.g., the top surface) of the first pillar structure 22 may be defined as the second upper surface 22_U2. An exposed portion of the upper surface (e.g., the top surface) of the first pillar structure 22 may be defined as a preliminary upper surface 22_pU. In other words, a portion of the upper surface (e.g., the top surface) of the first pillar structure 22 in contact with the second gate sacrificial layer 72 may be defined as the second upper surface 22_U2, and a portion of the upper surface (e.g., the top surface) of the first pillar structure 22 exposed through the opening op may be defined as the preliminary upper surface 22_pU.

The second gate sacrificial layer 72 may include, for example, poly silicon. The gate mask pattern 73 may include, for example, an insulating material. As an example, the gate mask pattern 73 may include silicon nitride.

Referring to FIGS. 4A, 4B, 4C, and 4D, an upper portion of the first pillar structure 22 exposed by the opening op may be removed. The second upper surface 22_U2 of the first pillar structure 22 may not be removed, when the upper portion of the first pillar structure 22 is removed.

For example, the level of the second upper surface 22_U2 of the first pillar structure 22 may not change during the upper portion of the first pillar structure 22 is removed. A level of the preliminary upper surface 22_pU of the first pillar structure 22 may be lowered as the upper portion of the first pillar structure 22 is removed. The level of the preliminary upper surface 22_pU of the first pillar structure 22 may be lower than the level of the second upper surface 22_U2 of the first pillar structure 22. As a result of the removal of the upper portion of the first pillar structure 22, the upper surface (e.g., the top surface) of the uppermost second semiconductor layer 83, the preliminary upper surface 22_pU of the first pillar structure 22, and the upper surface (e.g., the top surface) of the insulating isolation layer 21 may be located at (substantially) the same level. The upper surface (e.g., top surface) of the first pillar structure 22 and the upper surface (e.g., the top surface) of the insulating isolation layer 21 may be coplanar with each other. In an embodiment, the level of the upper surface (e.g., the top surface) of the first pillar structure 22 and the upper surface (e.g., the top surface) of the insulating isolation layer 21 may be lower than the level of the upper surface (e.g., the top surface) of the uppermost second semiconductor layer 83. Since the upper portion of the first pillar structure 22 is removed, the opening op on the first pillar structure 22 may be expanded.

In an embodiment, the upper portion of the first pillar structure 22 may be removed through a dry etching process.

Referring to FIGS. 5A, 5B, 5C, and 5D, a preliminary gate spacer pGS may be formed. The preliminary gate spacer pGS may be formed on the active patterns AP1 and AP2, the device isolation layers 12, the insulating isolation layers 21, the first semiconductor layers 82, the second semiconductor layers 83, the first pillar structures 22, the first gate sacrificial layers 71, the second gate sacrificial layers 72, and the gate mask patterns 73. The preliminary gate spacer pGS may fill a portion of the opening op. The preliminary gate spacer pGS may conformally cover the first gate sacrificial layers 71, the second gate sacrificial layers 72, the gate mask patterns 73, the second semiconductor layers 83, and the first pillar structures 22, which are exposed through the opening op. The preliminary gate spacer pGS may include, for example, an insulating material.

Referring to FIGS. 6A, 6B, 6C, and 6D, (at least a portion of) the preliminary gate spacer pGS, (at least a portion of) the first semiconductor layers 82, and (at least a portion of) the second semiconductor layers 83 may be etched through the opening op. As a result of the etching of the preliminary gate spacer pGS, the preliminary gate spacer pGS may form (e.g., may be divided into) the gate spacers GS and the capping insulating layer 27. Portions of the first and second semiconductor layers 82 and 83, which are overlapped with a space between the gate spacers GS in the third direction D3, may be etched. Each of the first semiconductor layers 82 may form (e.g., may be divided into) a plurality of semiconductor sacrificial patterns 88. Each of the second semiconductor layers 83 may form (e.g., may be divided into) a plurality of semiconductor patterns SP1 and SP2.

The insulating isolation layer 21 and the first pillar structure 22 may also be (at least partially) etched when the preliminary gate spacer pGS, the first semiconductor layers 82, and the second semiconductor layers 83 are etched. In other words, a portion of the first pillar structure 22, which is overlapped with the space between the gate spacers GS in the third direction D3, may be etched through the opening op. Thus, the level of the preliminary upper surface 22_pU of the first pillar structure 22 may be lowered. The lowered preliminary upper surface 22_pU of the first pillar structure 22 may be defined as the first upper surface 22_U1 of the first pillar structure 22.

In an embodiment, the preliminary gate spacer pGS, the first semiconductor layers 82, the second semiconductor layers 83, the insulating isolation layer 21, and the first pillar structure 22 may be removed through a dry etching process.

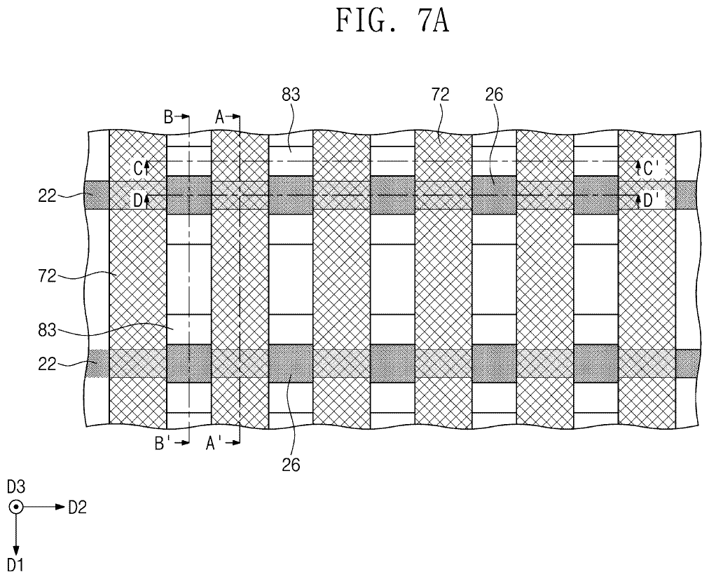

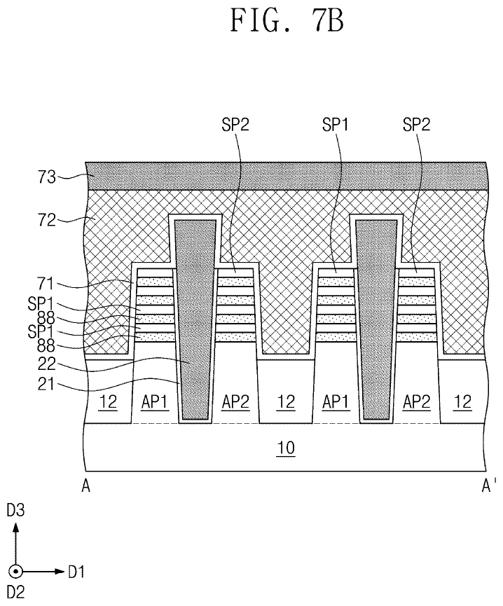

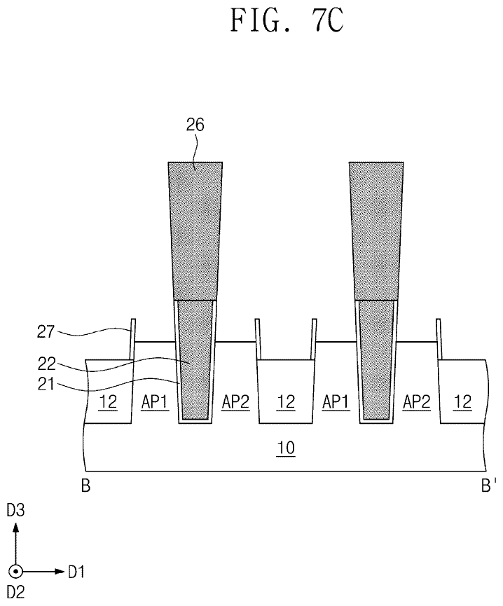

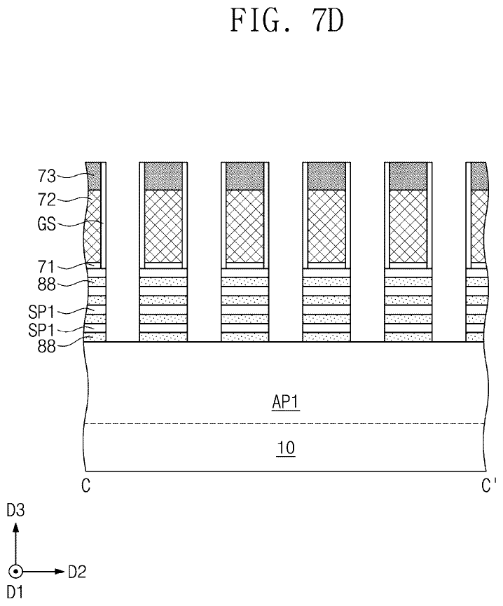

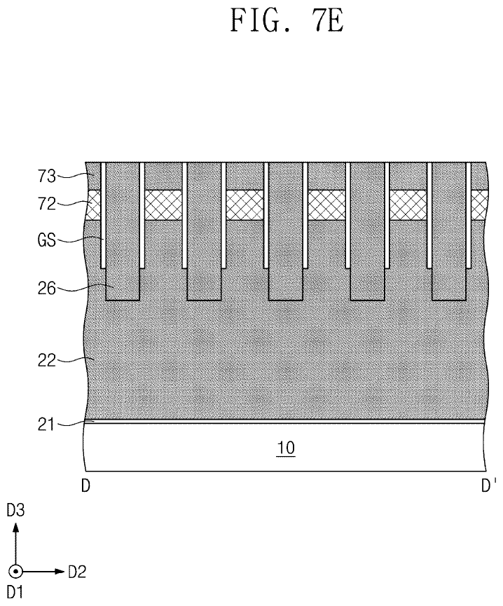

Referring to FIGS. 7A, 7B, 7C, 7D, and 7E, the second pillar structures 26 may be formed. The formation of the second pillar structures 26 may include forming a first insulating material through the opening op, etching a portion of the first insulating material to form an empty space, (at least partially) filling the empty space with a second insulating material, and removing the first insulating material. The second insulating material (at least partially) filling the empty space may be defined as the second pillar structure 26. The second pillar structure 26 may be formed in the space between the gate spacers GS and in the opening op, which is overlapped with the first pillar structure 22 in the third direction D3.

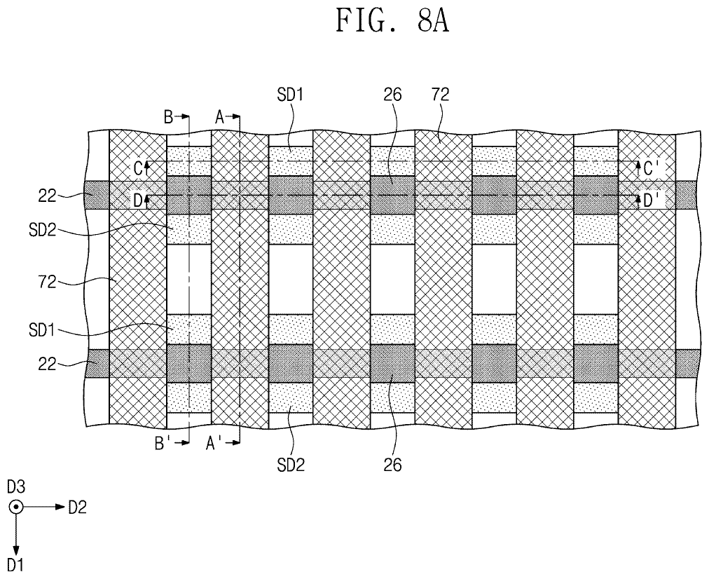

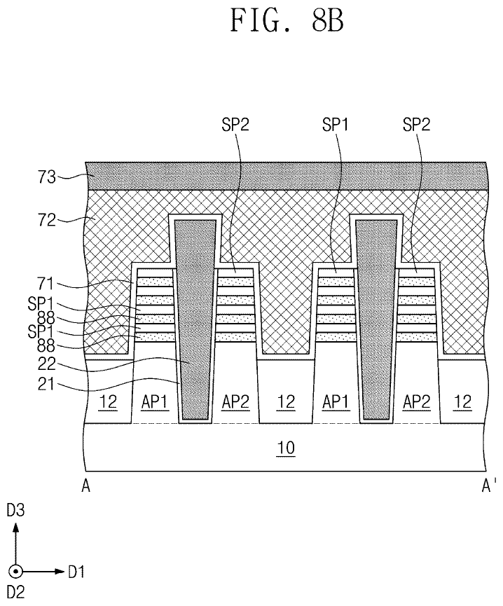

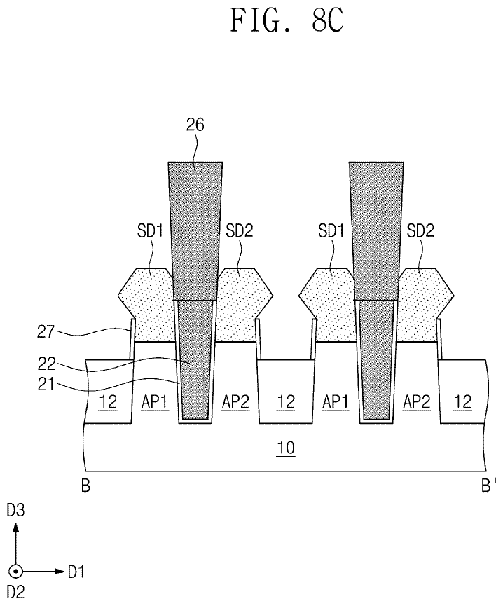

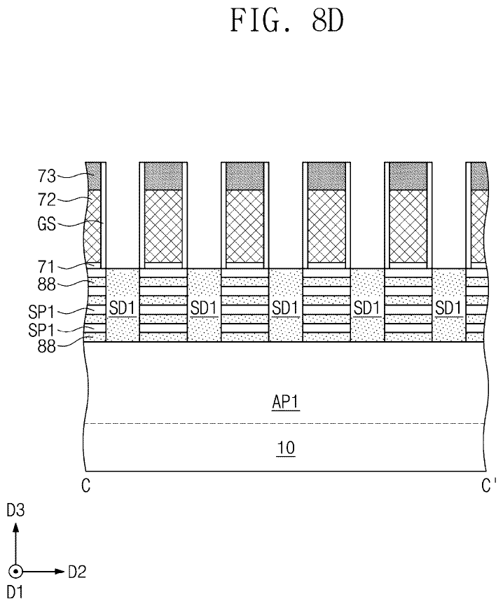

Referring to FIGS. 8A, 8B, 8C, 8D, and 8E, the first and second source/drain patterns SD1 and SD2 may be formed. The formation of the first and second source/drain patterns SD1 and SD2 may include performing an epitaxial growth process using the active patterns AP1 and AP2 as a seed layer.

Referring back to FIGS. 1A, 1B, 1C, 1D, and 1E, the cover insulating layer 52 may be formed to cover the device isolation layers 12, the first source/drain patterns SD1, the second source/drain patterns SD2, and the second pillar structures 26. The insulating layer 13 may be formed on the cover insulating layer 52.

The gate mask patterns 73, the second gate sacrificial layers 72, the first gate sacrificial layers 71, and the semiconductor sacrificial patterns 88 may be removed. Since the gate mask patterns 73, the second gate sacrificial layers 72, and the first gate sacrificial layers 71 are removed, an empty space may be formed to expose the first and second semiconductor patterns SP1 and SP2. The semiconductor sacrificial patterns 88 may be selectively removed through the empty space. In detail, an etching process of selectively etching the semiconductor sacrificial patterns 88 may be performed to leave the first and second semiconductor patterns SP1 and SP2 and to remove only the semiconductor sacrificial patterns 88. In an embodiment, the semiconductor sacrificial patterns 88 may be removed by a process of selectively removing silicon-germanium (SiGe). When the semiconductor sacrificial patterns 88 are removed, a portion of the insulating isolation layer 21 may also be removed. The intervening insulating patterns 23 may be formed as a result of the partial removal of the insulating isolation layer 21.

The gate insulating layers GI, the gate electrodes GEL and GE2, and the gate capping patterns GP may be formed in an empty space, which is formed by removing the gate mask patterns 73, the second gate sacrificial layers 72, the first gate sacrificial layers 71, and the semiconductor sacrificial patterns 88. The gate contacts 45 and the active contacts 41 may be formed.

In a semiconductor device according to an embodiment of the inventive concept, a level of an upper surface (e.g., a top surface) of a pillar structure may be lower than the uppermost level of a channel structure. Accordingly, in a process of forming a source/drain pattern, a residue may not be left on a side surface of the pillar structure, and this may make it possible to improve the electrical and reliability characteristics of the semiconductor device.

While example embodiments of the inventive concept have been particularly shown and described, it will be understood by one of ordinary skill in the art that variations in form and detail may be made therein without departing from the scope of the attached claims.

What is claimed is:

1. A semiconductor device, comprising:
a substrate that comprises a first active pattern and a second active pattern that are spaced apart from each other in a first direction;
a first channel structure on the first active pattern;
a first source/drain pattern on the first channel structure;
a first pillar structure between the first active pattern and the second active pattern; and
a second pillar structure on the first pillar structure,
wherein the first pillar structure comprises a first upper surface that is in contact with the second pillar structure and a second upper surface that is farther than the first upper surface from a lower surface of the substrate in a second direction,
wherein the first upper surface of the first pillar structure is closer than an uppermost surface of the first channel structure to the lower surface of the substrate in the second direction,
wherein the second upper surface of the first pillar structure is closer than an upper surface of the second pillar structure to the lower surface of the substrate in the second direction,
wherein the first direction is parallel with the lower surface of the substrate, and
wherein the second direction is perpendicular to the lower surface of the substrate.

2. The semiconductor device of claim 1, wherein the first channel structure comprises a plurality of semiconductor patterns, and
wherein the first upper surface of the first pillar structure is closer than a lower surface of an uppermost one of the semiconductor patterns to the lower surface of the substrate in the second direction.

3. The semiconductor device of claim 1, wherein the second pillar structure comprises a lower pattern and an upper pattern on the lower pattern,
wherein the lower pattern is in contact with the first source/drain pattern, and
wherein the upper pattern is spaced apart from the first source/drain pattern.

4. The semiconductor device of claim 3, further comprising: a cover insulating layer on the first source/drain pattern,
wherein the lower pattern is spaced apart from the cover insulating layer, and
wherein the upper pattern is in contact with the cover insulating layer.

5. The semiconductor device of claim 3, wherein the first channel structure comprises a plurality of semiconductor patterns, and
wherein a thickness of the lower pattern in the second direction is greater than a thickness of one of the semiconductor patterns in the second direction.

6. The semiconductor device of claim 1, further comprising: an insulating isolation layer between the first active pattern and the first pillar structure in the first direction,
wherein an upper surface of the insulating isolation layer is closer than the uppermost surface of the first channel structure to the lower surface of the substrate in the second direction.

7. The semiconductor device of claim 1, wherein a distance between a lower surface of the first pillar structure and the second upper surface of the first pillar structure in the second direction is less than a distance between a lower surface of the second pillar structure and the upper surface of the second pillar structure in the second direction.

8. The semiconductor device of claim 1, wherein a width of the second pillar structure in the first direction decreases as the second pillar structure extends toward the lower surface of the substrate in the second direction.

9. The semiconductor device of claim 1, further comprising:
a first gate electrode on the first active pattern; and
a gate spacer on a side surface of the first gate electrode,
wherein the gate spacer comprises:
a first side surface in contact with the first pillar structure;
a second side surface in contact with the second pillar structure; and
a connection surface between the first side surface and the second side surface,
wherein the connection surface is farther than the first upper surface of the first pillar structure from the lower surface of the substrate in the second direction, and
wherein the connection surface is closer than the second upper surface of the first pillar structure to the lower surface of the substrate in the second direction.

10. The semiconductor device of claim 1, wherein a width of the first upper surface of the first pillar structure in the first direction is less than a width of the upper surface of the second pillar structure in the first direction.

11. The semiconductor device of claim 1, wherein the upper surface of the second pillar structure is farther than an upper surface of the first source/drain pattern from the lower surface of the substrate in the second direction.

12. A semiconductor device, comprising:
a substrate that comprises a first active pattern and a second active pattern that are spaced apart from each other in a first direction;
a first channel structure that overlaps the first active pattern in a second direction;
a first source/drain pattern that is electrically connected to the first channel structure;
a first pillar structure between the first active pattern and second active pattern; and
a second pillar structure on the first pillar structure,
wherein the second pillar structure comprises:
a lower surface in contact with the first pillar structure;
an upper surface farther than an upper surface of the first source/drain pattern from a lower surface of the substrate in the second direction; and
a first side surface that is on the lower surface of the second pillar structure and on the upper surface of the second pillar structure,
wherein the first side surface of the second pillar structure is in contact with the first source/drain pattern,
wherein the first direction is parallel with the lower surface of the substrate, and
wherein the second direction is perpendicular to the lower surface of the substrate.

13. The semiconductor device of claim 12, further comprising: a cover insulating layer that at least partially extends around the first source/drain pattern,
wherein the cover insulating layer comprises an intervening portion between the first source/drain pattern and the second pillar structure in the first direction.

14. The semiconductor device of claim 13, wherein the intervening portion of the cover insulating layer is in contact with the first side surface of the second pillar structure.

15. The semiconductor device of claim 13, wherein the second pillar structure comprises a lower pattern and an upper pattern on the lower pattern, and
wherein the intervening portion of the cover insulating layer is in contact with the upper pattern.

16. The semiconductor device of claim 12, wherein the second pillar structure further comprises a second side surface that is in contact with the first pillar structure.

17. The semiconductor device of claim 16, further comprising:
a first gate electrode that overlaps the first active pattern in the first direction and/or the second direction; and
a gate spacer on a side surface of the first gate electrode,
wherein the second side surface of the second pillar structure is in contact with the gate spacer.

18. A semiconductor device, comprising:
a substrate that comprises a first active pattern and a second active pattern that are spaced apart from each other in a first direction;
a first channel structure that overlaps the first active pattern in a second direction;
a second channel structure that overlaps the second active pattern in the second direction;
a first gate electrode that overlaps the first active pattern in the first direction and/or the second direction;
a second gate electrode that overlaps the second active pattern in the first direction and/or the second direction;
a first source/drain pattern that is electrically connected to the first channel structure;
a second source/drain pattern that is electrically connected to the second channel structure;
a first pillar structure between the first channel structure and the second channel structure in the first direction;
an insulating isolation layer between the first active pattern and the first pillar structure;
a second pillar structure on the first pillar structure; and
a gate spacer on a side surface of the first gate electrode,
wherein the gate spacer is between the first pillar structure and the second pillar structure,
wherein the first direction is parallel with a lower surface of the substrate, and
wherein the second direction is perpendicular to the lower surface of the substrate.

19. The semiconductor device of claim 18, wherein the first pillar structure comprises:
a first side surface between the first channel structure and the second channel structure in the first direction;
a second side surface between the first source/drain pattern and the second source/drain pattern in the first direction;
a third side surface that is in contact with the second pillar structure; and
a fourth side surface that is in contact with the gate spacer.

20. The semiconductor device of claim 18, wherein the first source/drain pattern comprises an inner side surface that faces the second source/drain pattern, and
wherein the inner side surface comprises a first portion that is in contact with the insulating isolation layer and a second portion that is in contact with the second pillar structure.
